(19) United States
(12) Patent Application Publication
(10) Pub. No.: US 2008/0211511 A1
(43) Pub. Date: Sep. 4, 2008

(54) Method of Generating Fault Indication in Feeder Remote Terminal Unit for Power Distribution Automation System

(75) Inventors: Myeon Song Choi, Seoul (KR); Seong Il Lim, Yongin-si (KR); Seung Jae Lee, Seongnam-si (KR)

Correspondence Address: THE WEBB LAW FIRM, P.C., 700 KOPPERS BUILDING, 436 SEVENTH AVENUE, PITTSBURGH, PA, 15219, US

(73) Assignee: Myongji University Industry and Academia Cooperation Foundation, Gyeonggi-do (KR)

(21) Appl. No.: 12/019,762

(22) Filed: Jan. 25, 2008

(30) Foreign Application Priority Data
Jan. 26, 2007 (KR) 10-2007-0008472

(51) Int. Cl. G01R 31/08

(52) U.S. Cl. 324/522

(57) ABSTRACT

The present invention relates to a method of generating fault indication in a feeder remote terminal unit for a power distribution automation system. The method is performed in a distribution system that includes a plurality of feeder remote terminal units, which are installed in respective sections of a line and are configured to measure voltage, current and a phase difference of the line, and a central control unit for determining whether a fault occurs and controlling operation of the feeder remote terminal units. In the method, phases are measured by each of the feeder remote terminal units. The phase of a zero-sequence current is compared with that of a zero-sequence voltage. A direction of a fault current is calculated, and fault indication information is generated in the calculated direction of the fault current.

### BACKGROUND OF THE INVENTION

1. Field of the Invention

The present invention relates, in general, to a method of generating fault indication in a feeder remote terminal unit for a power distribution automation system, and, more particularly, to a method of generating fault indication in a feeder remote terminal unit for a power distribution automation system, which obtains both the phase of a zero-sequence voltage and the phase of a zero-sequence current, and generates fault indication information when the phases satisfy certain conditions.

2. Description of the Related Art

Generally, in a distribution system, an ungrounded method is used in a system having a short line and a low voltage. In such a line, since ground capacitance is low, charge current is not high. When a single-line ground fault occurs in the line of an ungrounded system, fault current, attributable to ground capacitance having a sound phase, flows into a fault point, but the magnitude of the fault current is very low, and thus the supply of power can be continuously performed. Further, there is an advantage in that, since principal transformers are wired in a Δ-Δ shape, power transmission can be continuously performed by switching the wiring shape over to a V-wiring shape at the time of examining the transformers for faults or repairing the transformers.

However, when an ungrounded system is extended, capacitance is increased. And when a single-line ground fault occurs, an intermittent arc ground fault is caused by charge current, and thus an abnormal voltage is generated. Further, when a single-line ground fault occurs, the magnitude of fault current is equal to or less than several amperes, so that the detection of a fault is difficult, and thus it is difficult to predict the precise operation of a ground fault protection relay. Further, when protection fails, the range of the ground fault may increase, and the ground fault may develop into a short circuit fault.

When a fault occurs in a distribution system, the manager of the distribution system must visually check the sections of wide power transmission/distribution lines so as to detect a fault point if there is no device for easily and automatically detecting the type and location of fault. Such an operation requires a lot of manpower and high costs associated with outage. Therefore, the need for research into practical methods of determining a fault type and detecting a fault point increases.

A domestic power distribution automation system is a system which allows a power distribution control center to remotely monitor and control distribution systems using information about Feeder Remote Terminal Units (FRTUs), which are distributed in remote places, on the basis of power system operating technology and IT technology, and which automatically detects a faulty section and automatically collects line operation information about, for example, voltage, current, and waveforms. Such a power distribution automation system is a composite control system for efficiently operating distribution systems.

Each feeder remote terminal unit of a power distribution automation system periodically transmits the status information of a distribution system to the central unit of the power distribution automation system in a normal mode, and transmits abnormality information related to faults to the central unit when a fault occurs in a distribution system.

When a fault occurs in power equipment in the distribution system, high fault current flows from a power stage to a fault location. Since the distribution systems are radially connected to each other, a protection device placed upstream of the faulty equipment detects fault current, and provides a command to a circuit breaker, thus enabling removal of the fault.

After the fault removal operation has been completed, a wide outage occurs in distribution systems located downstream of the operated circuit breaker. The power distribution automation system must recover outage sections, other than the faulty section, as fast as possible.

First, when a fault occurs, the central unit of the power distribution automation system must analyze fault indication information received from respective feeder remote terminal units of a distribution system in order to detect a faulty section, precisely determine a faulty section, and transmit commands required for recovery to respective feeder remote terminal units so as to switch loads placed in the remaining outage sections, rather than the determined faulty section, over to other sound feeders, thus recovering the outage sections. When a fault occurs in a stage placed downstream of the location at which the feeder remote terminal unit is installed, on the basis of a substation power source, each feeder remote terminal unit of the power distribution automation system senses fault current, generates fault indication information in the case where the flow of the fault current continues for a predetermined period of time, and transmits the fault indication information to the central unit, thus enabling the central unit to detect a faulty section.

The feeder remote terminal unit of the distribution system determines that a fault occurs and generates fault indication information if a current equal to or greater than a preset minimum operating current (minimum pick up) continuously flows for a predetermined period of time or longer, on the assumption that a feeder remote terminal unit placed upstream of a fault point is subjected to fault current flowing from a power stage to the fault point, whereas a feeder remote terminal unit placed downstream of the fault point is not subjected to the fault current when a fault occurs.

However, in the case of a ground fault, a feeder remote terminal unit in a section placed upstream of a faulty section is subjected to fault current, and precisely generates fault indication information. However, there is a problem in that a feeder remote terminal unit in a section placed downstream of the faulty section also erroneously generates fault indication information because the zero-sequence component of fault current supplied from a load stage exists.

Further, when a large electric motor is placed in a load stage, the electric motor functions as a load in a normal mode. At this time, when a fault occurs in a line, the electric motor is continuously rotated by inertia and, in doing so, functions as an electric generator, so that fault current may be supplied from the load stage to the fault point. Similarly, even when a distributed power generator exists in the load stage, fault current may be supplied from the distributed power generator to the fault point. In this case as well, there is a problem in that, since a feeder remote terminal unit placed downstream of a fault point erroneously determines that a fault has occurred downstream of the location at which the feeder remote terminal unit is installed due to high fault current supplied from the electric motor load stage, erroneous fault indication information is generated.

### SUMMARY OF THE INVENTION

Accordingly, the present invention has been made keeping in mind the above problems occurring in the prior art, and an object of the present invention is to provide a method of generating fault indication in a feeder remote terminal unit for a power distribution automation system, which compares the phase of a zero-sequence voltage with the phase of a zero-phase current and generates fault indication when the phases satisfy certain conditions.

Another object of the present invention is to provide a method of generating fault indication in a feeder remote terminal unit for a power distribution automation system, which obtains both the phase of a positive-sequence voltage and the phase of a positive-sequence current and determines the difference between the phase of the positive-sequence voltage and the phase of the positive-sequence current when the direction of current is the direction from a power stage to a load stage, and then generates fault indication when the phase difference satisfies certain conditions.

In order to accomplish the above objects, the present invention provides a method of generating fault indication in a feeder remote terminal unit for a power distribution automation system in a method of detecting a faulty section in a distribution system, the distribution system including a plurality of feeder remote terminal units, which are installed in respective sections of a line and are configured to measure voltage, current and a phase difference of the line, a fault line detection unit for detecting whether a fault occurs in the line, and a central control unit for determining whether a fault occurs through the feeder remote terminal units and the fault line detection unit, and controlling operation of the feeder remote terminal units, the method comprising the steps of each feeder remote terminal unit measuring a phase of a zero-sequence voltage and a phase of a zero-sequence current, comparing the phase of the zero-sequence current with the phase of the zero-sequence voltage measured at the phase measurement step, and calculating a direction of fault current after the phase comparison step, and generating fault indication information in the calculated direction of the fault current.

Preferably, the fault indication information may be generated if the phase of the zero-sequence current is close to an imaginary axis of a second quadrant when a direction in which current is measured is set to a direction from a power stage to a load stage at the phase comparison step.

In addition, the present invention provides a method of generating fault indication in a feeder remote terminal unit for a power distribution automation system in a method of detecting a faulty section in a distribution system, the distribution system including a plurality of feeder remote terminal units, which are installed in respective sections of a line and are configured to measure voltage, current and a phase difference of the line, a fault line detection unit for detecting whether a fault occurs in the line, a central control unit for determining whether a fault occurs through the feeder remote terminal units and the fault line detection unit, and controlling operation of the feeder remote terminal units, and a load stage having an electric motor, the method comprising the steps of each feeder remote terminal unit measuring a phase of a positive-sequence voltage and a phase of a positive-sequence current, comparing the phase of the positive-sequence current with the phase of the positive-sequence voltage measured at the phase measurement step, and calculating a direction of fault current after the phase comparison step, and generating fault indication information in the calculated direction of the fault current.

Preferably, the fault indication information may be generated if the phase of the positive-sequence current is close to an imaginary axis of a fourth quadrant when a direction in which current is measured is set to a direction from a power stage to the load stage at the phase comparison step.

Preferably, the direction of the current measured by the feeder remote terminal unit may be a direction from the power stage to the load stage when the phase of the positive-sequence current is placed in a first quadrant or the fourth quadrant on a basis of the phase of the positive-sequence voltage measured by the feeder remote terminal unit in a normal mode.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram showing an example of a system for determining a faulty section from fault indication information according to the present invention;

FIG. 2 is a block diagram showing an equivalent circuit when a fault occurs in a distribution system according to the present invention;

FIG. 3 is a block diagram showing an equivalent zero-sequence circuit when a ground fault occurs in a distribution system according to the present invention;

FIG. 4 is a vector diagram showing variables measured in an area placed upstream of a fault point;

FIGS. 5A and 5B are vector diagrams showing variables measured in an area placed downstream of a fault point;

FIG. 6 is a block diagram showing an equivalent circuit when a fault occurs in a distribution system having an electric motor load according to the present invention;

FIG. 7 is a block diagram showing an equivalent positive-sequence circuit when a fault occurs in a distribution system having an electric motor load according to the present invention; and

FIG. 8 is a vector diagram showing variables of a positive-sequence circuit having an electric motor load.

### DESCRIPTION OF THE PREFERRED EMBODIMENTS

Hereinafter, embodiments of the present invention will be described in detail with reference to the attached drawings.

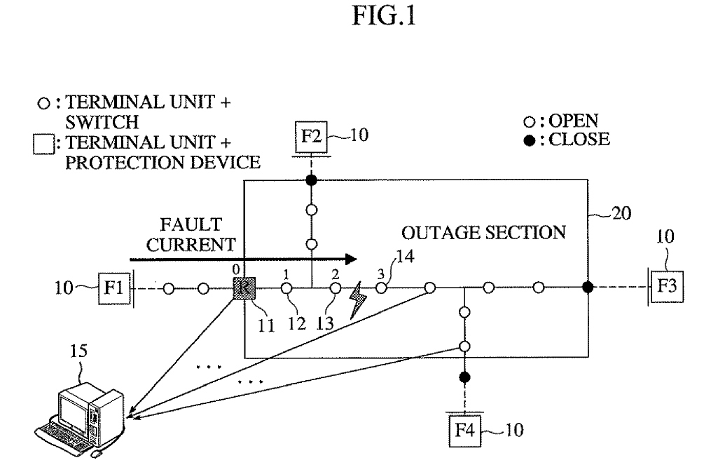

FIG. 1 is a block diagram showing an example of a system for determining a faulty section from fault indication information according to the present invention. FIG. 1 illustrates a power distribution automation system that is configured to include a first feeder remote terminal unit 11, a second feeder remote terminal unit 12, a third feeder remote terminal unit 13, a fourth feeder remote terminal unit 14, and a fault line detection unit 10, which are installed on a line, and a central control unit 15, and that is configured to find and isolate a faulty section and switch a sound section placed downstream of the faulty section over to a tieline, thus continuing to supply power to all loads without interrupting the supply of power.

The first feeder remote terminal unit 11 includes a protection device, and each of the second feeder remote terminal unit 12, the third feeder remote terminal unit 13, and the fourth feeder remote terminal unit 14 includes a switch.

When a fault occurs in a stage placed downstream of the location at which the feeder remote terminal unit is installed on the basis of a substation power source, each feeder remote terminal unit senses a fault current, generates fault indication information when the fault current continues for a predetermined period of time, and transmits the fault indication information to the central control unit 15, thus enabling the central control unit 15 to detect a faulty section. That is, each of the feeder remote terminal units 11, 12, 13, and 14 measures voltages and currents between sub-lines on the line, the difference between the phases of a zero-sequence voltage and a zero-sequence current, and the magnitudes of the zero-sequence voltage and the zero-sequence current, individually transmits information about the measured phase difference to the central control unit 15 when there is a request from the central control unit 15, receives a command from the central control unit 15, and performs an operation of interrupting the line and opening or closing the switch in response to the command.

The fault line detection unit 10 determines whether a fault occurs in its own line when a fault occurs in a line, and transmits fault information to the central control unit 15.

The central control unit 15 performs the overall operation of the power distribution automation system, searches the topology of a given line when the fault line detection unit 10 transmits fault information, requests information about voltages, currents and phase differences from the feeder remote terminal units located on the given line, and compares pieces of information about respective phase differences transmitted from respective feeder remote terminal units located on the given line with each other.

Further, the central control unit 15 performs the operation of determining that a section in which feeder remote terminal units on the given line are installed is a faulty section when certain conditions are satisfied on the basis of data, such as voltages, currents and phase differences. When a sound section exists within the faulty section, the central control unit 15 performs an operation of closing a switch connected to the sound section, disconnecting the feeder remote terminal units in the faulty section, isolating the faulty section from the distribution system, and continuing to supply power to loads in a sound section without interrupting the supply of power.

In an embodiment of the present invention, the central control unit 15 determines system status using the information collected from the first feeder remote terminal unit 11, the second feeder remote terminal unit 12, the third feeder remote terminal unit 13, and the fourth feeder remote terminal unit 14, and transmits a command for controlling the switch of a suitable feeder remote terminal unit to each feeder remote terminal unit.

The operation of the power distribution automation system is described below. As shown in FIG. 1, when it is assumed that a fault occurs in a section between the third and fourth feeder remote terminal units 13 and 14, fault current flows from a power stage up to a fault point.

At this time, when a protection device included in the first feeder remote terminal unit 11 is operated to cut off fault current, an outage section 20 is formed. Each feeder remote terminal unit in the outage section 20 transmits information about an abnormal situation to the central control unit 15 because an abnormal situation, that is, outage, occurs.

Therefore, the information, transmitted from the first to third feeder remote terminal units 11, 12, and 13, which suffer from the fault current, to the central control unit 15, includes Fault Indication (FI) information. However, the information transmitted from other feeder remote terminal units, which include the fourth feeder remote terminal unit 14, and do not suffer from the fault current, to the central control unit 15 does not include any fault indication information.

The central control unit 15 puts the information transmitted from all of the feeder remote terminal units included in the outage section 20 together, detects a faulty section and an outage section, transmits a command for opening the switch to both the third and fourth feeder remote terminal units 13 and 14 so as to isolate the faulty section, and transmits a suitable command for controlling switches to respective feeder remote terminal units included in the outage section 20 so as to recover the outage section 20.

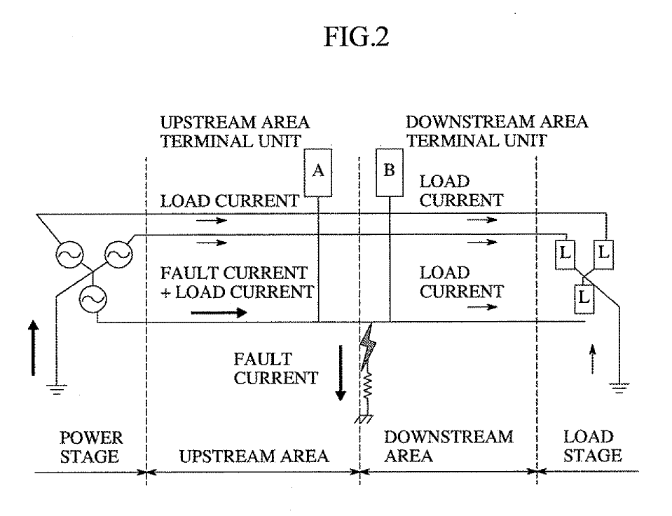

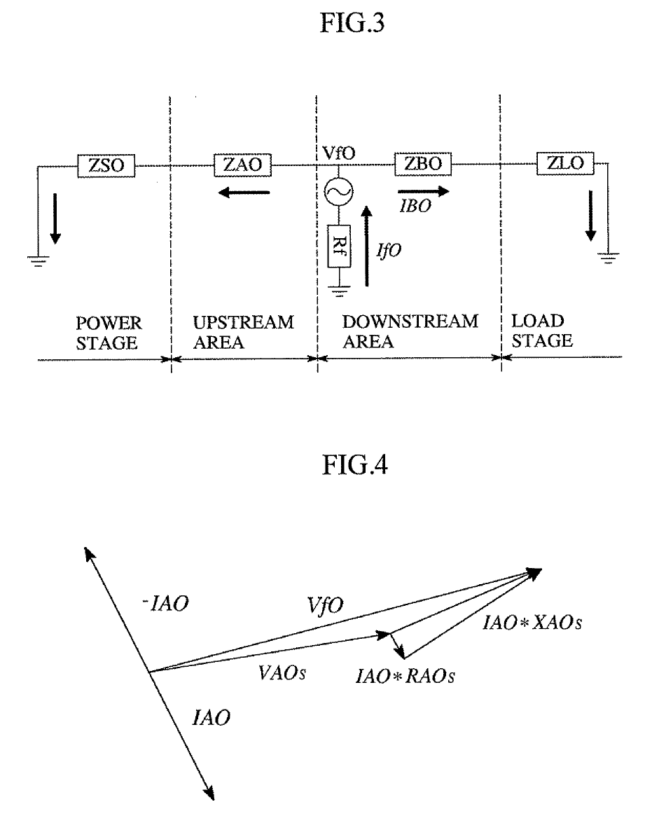

FIG. 2 is a block diagram showing an equivalent circuit when a fault occurs in a distribution system according to the present invention, and FIG. 3 is a block diagram showing an equivalent zero-sequence circuit when a ground fault occurs in a distribution system according to the present invention, and illustrates the distribution of fault current and zero-sequence current when it is assumed that a fault occurs in a line, in order to describe an operation in which a feeder remote terminal unit determines a fault point.

As shown in FIG. 2, on the assumption that a feeder remote terminal unit placed upstream of a fault point is subjected to fault current flowing from a power stage to the fault point at the time of a fault, whereas a feeder remote terminal unit placed downstream of the fault point is not subjected to the fault current, each feeder remote terminal unit determines that a fault has occurred if current equal to or greater than a preset minimum operating current (minimum pick up) continuously flows for a certain period of time or longer, and generates fault indication information.

However, as shown in FIG. 3, when a ground fault occurs in a distribution system, a zero-sequence voltage (Vf0) is generated at the fault point due to imbalance in three phases, and thus the zero-sequence component of the fault current (If0) flows.

The fault current is described on the basis of the zero-sequence voltage (Vf0) at the fault point. The zero-sequence component (If0) of the fault current flows to the power stage and the load stage around the fault point while branching into a zero-sequence current (IA0) for an upstream area and a zero-sequence current (IB0) for a downstream area. In this case, erroneous fault indication information is generated while the downstream area zero-sequence current (IB0), flowing from the fault point to the load stage, passes through the feeder remote terminal unit placed downstream of the fault point (for example, the fourth feeder remote terminal unit 14).

That is, a fault actually occurs in an area placed upstream of the fourth feeder remote terminal unit 14, but it is erroneously determined that the fault occurs in an area placed downstream of the fourth feeder remote terminal unit 14.

In order to prevent such erroneous determination, as shown in FIG. 3, since the fault current zero-sequence component (If0) flows to the upstream area and the downstream area in opposite directions around the fault point in the form of currents (IA0) and (IB0), fault indication information must be generated only in the upstream area in consideration of the direction of the zero-sequence component (If0) of the fault current. Therefore, since the zero-sequence component (If0) of the fault current flows due to the zero-sequence voltage (Vf0) of the fault point, the direction of the fault current zero-sequence component (If0) is calculated by comparing the phase of the fault point zero-sequence voltage (Vf0) with the phase of the fault current zero-sequence component (If0), and the calculated direction can be generated as fault indication information.

As shown in FIG. 3, the magnitude of the upstream area zero-sequence current (IA0) flowing from the fault point to the power stage is in inverse proportion to the sum of the zero-sequence impedance (ZS0) of the power stage and the zero-sequence impedance (ZA0) of the upstream area. Further, the difference between the phases of the fault point zero-sequence voltage (Vf0) and the upstream area zero-sequence current (IA0) is determined according to the ratio of the resistance to reactance of the sum of the power stage zero-sequence impedance (ZS0) and the upstream area zero-sequence impedance (ZA0). Therefore, the impedance of the sum of the power stage zero-sequence impedance (ZS0) and the upstream area zero-sequence impedance (ZA0) is close to the imaginary axis of the first quadrant of the plane because the resistance is much lower than the reactance.

FIG. 4 is a vector diagram showing variables measured in an area placed upstream of a fault point. As shown in FIG. 4, an upstream area zero-sequence voltage (VA0s) measured at an arbitrary measurement point placed upstream of the fault point is a value obtained by subtracting a line voltage drop between the fault point and the arbitrary measurement point from the fault point zero-sequence voltage (Vf0).

Therefore, the phase of the fault current zero-sequence component (IA0), flowing from the fault point to the power stage, is close to the imaginary axis of the fourth quadrant on the basis of the upstream area zero-sequence voltage (VA0s) measured at the arbitrary measurement point placed upstream of the fault point. However, in the case of the measurement direction of the feeder remote terminal unit, when the direction from the power stage to the load stage is set to a reference direction, the phase of the upstream area zero-sequence current (IA0), calculated for an area placed upstream of the fault point, is opposite that calculated in the reference direction, and thus it is close to 90 degrees in the second quadrant.

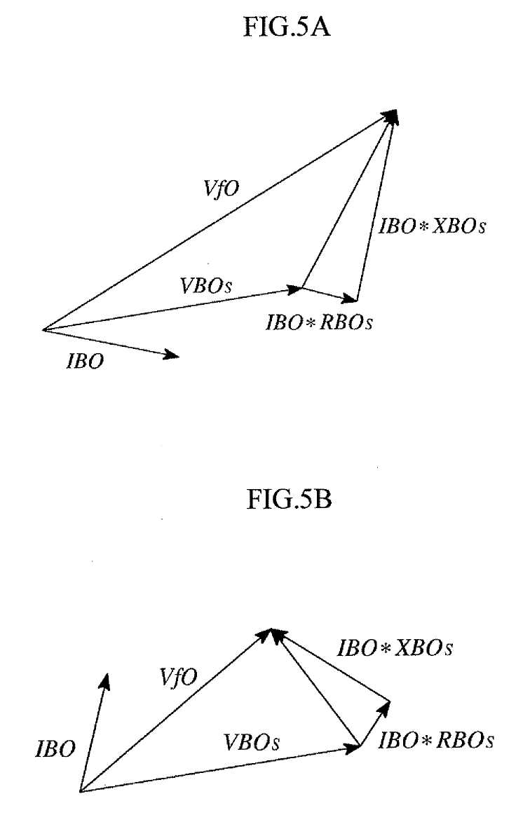

FIGS. 5A and 5B are vector diagrams showing variables measured in an area placed downstream of the fault point according to the present invention, and illustrate the vector diagrams showing the vectors between a downstream area zero-sequence current (IB0), flowing to the load stage, and the downstream area zero-sequence voltage (VB0s), measured at an arbitrary measurement point placed downstream of the fault point, on the basis of the fault point zero-sequence voltage (Vf0).

As shown in FIG. 5A, when a current, having a phase lagging behind that of the fault point zero-sequence voltage (Vf0), flows due to a lagging load, the phase of the downstream area zero-sequence current (IB0) lags behind that of the downstream area zero-sequence voltage (VB0s). However, in the case of a leading load, as shown in FIG. 5B, a leading current flows, and thus the phase of the downstream area zero-sequence current (IB0) leads that of the downstream area zero-sequence voltage (VB0s).

Therefore, the phase of the downstream area zero-sequence current (IB0), measured by the feeder remote terminal unit placed downstream of the fault point and flowing in the direction from the power stage to the load stage, is placed in the first or fourth quadrant on the basis of the zero-sequence voltage (Vf0) at the fault point when the measurement direction of current is the direction from the power stage to the load stage.

Accordingly, in order to prevent erroneous fault indication information from being generated when zero-sequence current flowing from the area placed downstream of the fault point to the load stage is equal to or greater than a preset value at the time of a ground fault, it can be determined that correct fault indication information is generated according to additional conditions, in which the phases of the zero-sequence voltage and the zero-sequence current are obtained, and fault indication information is generated only when the phase of the zero-sequence current is close to the imaginary axis of the second quadrant on the basis of the phase of the zero-sequence voltage, in addition to existing principles, in which fault indication information is generated using only the magnitude and duration conditions of the zero-sequence current.

As described above, when the feeder remote terminal unit transmits the fault indication information to the central control unit 15 using both the zero-sequence voltage and the zero-sequence current, the central control unit 15 detects a faulty section using voltages and currents between sub-lines on the line, zero-sequence voltages, and zero-sequence currents, which are measured by respective line feeder remote terminal units 11, 12, 13 and 14 placed on the fault line.

Therefore, when the method of the present invention is used, even if the zero-sequence current, flowing from the fault point to the load stage, is present in the area placed downstream of the fault point, the additional conditions (close to the imaginary axis of the second quadrant) are not satisfied, and thus erroneous fault indication information is not generated.

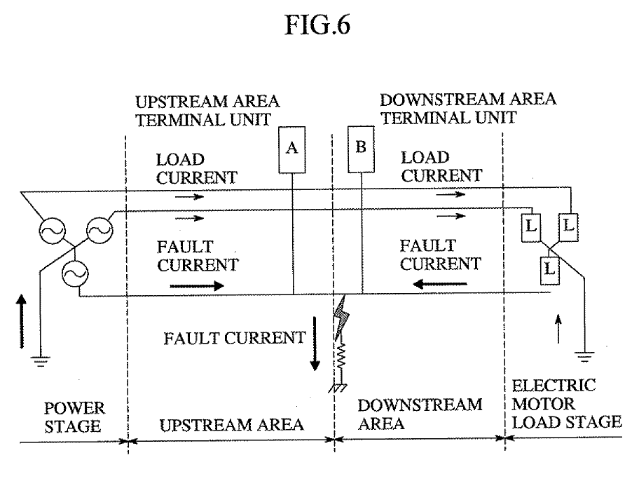

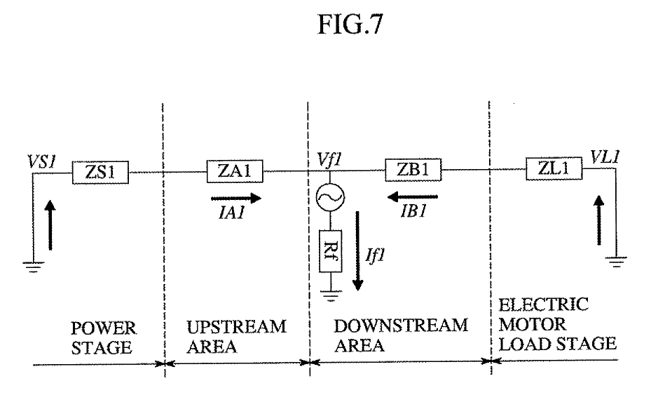

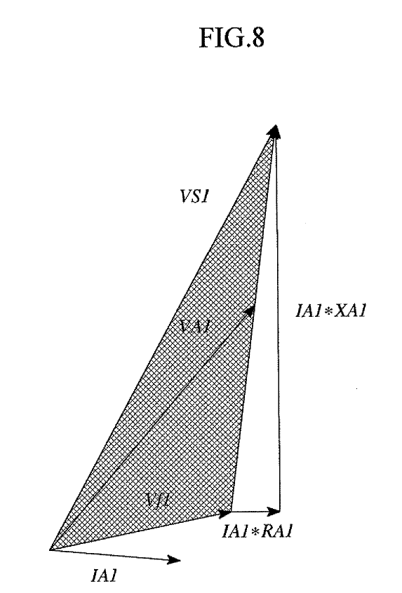

FIG. 6 is a block diagram showing an equivalent circuit when a fault occurs in a distribution system having an electric motor load according to the present invention, FIG. 7 is a block diagram showing an equivalent positive-sequence circuit when a fault occurs in a distribution system having an electric motor load according to the present invention, and FIG. 8 is a vector diagram showing the variables of a positive-sequence circuit having an electric motor load. As shown in FIG. 6, when a large electric motor is present in the load stage, the electric motor functions as a load in a normal mode. However, when a fault occurs in a line, the electric motor is continuously rotated by inertia and functions as an electric generator, so that fault current may be supplied from the load stage to a fault point. Similarly, when a distributed power generator is present in the load stage, fault current may be supplied from the distributed power generator to the fault point at the time of a fault.

As shown in FIG. 7, in the equivalent positive-sequence circuit of a distribution system, in which an electric motor load is present regardless of a ground fault or a short circuit, in which both the power stage and the load stage supply positive-sequence voltage, and in which a fault occurs, the positive-sequence component of fault current flows from the power stage to the fault point because the positive-sequence voltage (VS1) of the power stage is higher than the positive-sequence voltage (Vf1) of the fault point. Similarly, since the positive-sequence voltage (VL1) of the load stage, attributable to the operation of the electric generator in the electric motor load stage, is higher than the positive-sequence voltage (Vf1) of the fault point, the positive-sequence component of the fault current is supplied from the load stage to the fault point.

Meanwhile, as shown in FIG. 8, since the upstream area positive-sequence voltage (VA1), measured in an area placed upstream of the fault point, is present between the power stage positive-sequence voltage (VS1) and the fault point positive-sequence voltage (VF1), it exists in the line connecting the two voltages.

Since the upstream area positive-sequence voltage (VA1) measured in the area placed upstream of the fault point is present between the power stage positive-sequence voltage (VS1) and the fault point positive-sequence voltage (Vf1), the area in which the phase angle of the upstream area positive-sequence voltage (VA1) exists is the region indicated by the oblique lines in the vector diagram of FIG. 8.

In this case, since the positive-sequence impedance (ZA1) of the upstream area of the line has high reactance, the phase angle of the upstream area positive-sequence current (IA1), measured in the area placed upstream of the fault point, is close to the imaginary axis of the fourth quadrant on the basis of the phase angle of the upstream area positive-sequence voltage (VA1). Therefore, in the feeder remote terminal unit placed upstream of the fault point, the difference between the phase of the upstream area positive-sequence current (IA1) and the phase of the upstream area positive-sequence voltage (VA1), which are measured in the direction from the power stage to the load stage, is about −90 degrees.

However, in the feeder remote terminal unit placed downstream of the fault point, positive-sequence current (IB1) measured in the direction from the power stage to the load stage has the opposite measurement direction, and thus the phase difference thereof with respect to the downstream area positive-sequence voltage (VB1) is about 90 degrees.

Therefore, in order to prevent an error in which the electric motor of the load stage functions as an electric generator and high fault current is supplied from the load stage to the fault point at the time of a short circuit or a ground fault between lines in the case where the electric motor is present in the load stage, the following conditions must be additionally applied to existing principles, in which the feeder remote terminal unit generates fault indication information on the basis of the magnitude and duration of line current. That is, when the direction of current to be measured is the direction from the power stage to the load stage, the phase of the upstream area positive-sequence voltage (VA1) and the phase of the upstream area positive-sequence current (IA1) are obtained, and the feeder remote terminal unit placed upstream of the fault point can determine that correct fault indication information is generated only when the phase difference of the upstream area positive-sequence current (IA1) with respect to the phase of the upstream area positive-sequence voltage (VA1) is close to −90 degrees.

Accordingly, when the method of the present invention is used, the additional conditions (phase difference is close to −90 degrees) are not satisfied in the area placed downstream of the fault point, so that erroneous fault indication information is not generated.

Meanwhile, in order for each feeder remote terminal unit of the power distribution automation system to generate fault indication information, the feeder remote terminal unit must know whether the direction of current, measured at the location at which the feeder remote terminal unit is installed, is the direction from the power stage to the load stage, or the opposite direction.

However, in the distribution system, since a power stage and a load stage viewed from a feeder remote terminal unit are changed at any time due to variation in the location of a connection point attributable to variation in system, the directions of the power stage and the load stage must be recognized using the direction of the current measured by the feeder remote terminal unit. However, since the distribution system has a radial structure in which the power stage is a start point, load current always flows in the direction from the power stage to the load stage in a normal mode.

Therefore, a method of determining whether current is measured in the direction from the power stage to the load stage or in the opposite direction is described below.

In a normal mode, when the phase of positive-sequence current is placed in the first or fourth quadrant on the basis of the positive-sequence voltage measured by each feeder remote terminal unit, the current measurement direction is the direction from the power stage to the load stage. However, when the phase is placed in the second or third quadrant, the direction from the power stage to the load stage is opposite the current measurement direction.

As described above, according to a method of generating fault indication in a feeder remote terminal unit for a power distribution automation system, the phases of a zero-sequence voltage and a zero-sequence current are obtained and are compared with each other, and fault indication information is generated only when the phases satisfy certain conditions, in addition to existing principles, in which fault indication information is generated using only the conditions of the magnitude and duration of zero-sequence current.

Accordingly, there is an advantage in that, since the certain conditions are not satisfied even if there is zero-sequence current, flowing from a fault point to a load stage, in a location between the fault point, erroneous fault indication information is not generated.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of generating fault indication in a feeder remote terminal unit for a power distribution automation system in a method of detecting a faulty section in a distribution system, the distribution system including a plurality of feeder remote terminal units, which are installed in respective sections of a line and are configured to measure voltage, current and a phase difference of the line, a fault line detection unit for detecting whether a fault occurs in the line, and a central control unit for determining whether a fault occurs through the feeder remote terminal units and the fault line detection unit, and controlling operation of the feeder remote terminal units, the method comprising the steps of:
each feeder remote terminal unit measuring a phase of a zero-sequence voltage and a phase of a zero-sequence current;
comparing the phase of the zero-sequence current with the phase of the zero-sequence voltage measured at the phase measurement step; and
calculating a direction of fault current after the phase comparison step, and generating fault indication information in the calculated direction of the fault current.

2. The method according to claim 1, wherein the fault indication information is generated if the phase of the zero-sequence current is close to an imaginary axis of a second quadrant when a direction in which current is measured is set to a direction from a power stage to a load stage at the phase comparison step.

3. A method of generating fault indication in a feeder remote terminal unit for a power distribution automation system in a method of detecting a faulty section in a distribution system, the distribution system including a plurality of feeder remote terminal units, which are installed in respective sections of a line and are configured to measure voltage, current and a phase difference of the line, a fault line detection unit for detecting whether a fault occurs in the line, a central control unit for determining whether a fault occurs through the feeder remote terminal units and the fault line detection unit, and controlling operation of the feeder remote terminal units, and a load stage having an electric motor, the method comprising the steps of:
each feeder remote terminal unit measuring a phase of a positive-sequence voltage and a phase of a positive-sequence current;
comparing the phase of the positive-sequence current with the phase of the positive-sequence voltage measured at the phase measurement step; and
calculating a direction of fault current after the phase comparison step, and generating fault indication information in the calculated direction of the fault current.

4. The method according to claim 3, wherein the fault indication information is generated if the phase of the positive-sequence current is close to an imaginary axis of a fourth quadrant when a direction in which current is measured is set to a direction from a power stage to the load stage at the phase comparison step.

5. The method according to claim 2 or 4, wherein the direction of the current measured by the feeder remote terminal unit is a direction from the power stage to the load stage when the phase of the positive-sequence current is placed in a first quadrant or the fourth quadrant on a basis of the phase of the positive-sequence voltage measured by the feeder remote terminal unit in a normal mode.
